(19) United States
(12) Patent Application Publication
(10) Pub. No.: US 2026/0123422 A1
(43) Pub. Date: Apr. 30, 2026

(54) SEMICONDUCTOR DEVICE AND SEMICONDUCTOR PACKAGE INCLUDING THE SAME

(71) Applicant: Samsung Electronics Co., Ltd., Suwon-si (KR)

(72) Inventors: Eunsuk Jung, Suwon-si (KR); Pilkyu Kang, Suwon-si (KR); Jaewha Park, Suwon-si (KR); Kyungseok Oh, Suwon-si (KR)

(21) Appl. No.: 19/261,709

(22) Filed: Jul. 7, 2025

(30) Foreign Application Priority Data
Oct. 25, 2024 (KR) 10-2024-0147933

(51) Int. Cl. H01L 23/373; H01L 23/00; H01L 23/48; H01L 23/538; H01L 25/065; H01L 25/18; H10B 80/00

(52) U.S. Cl. CPC H10W 40/259; H10B 80/00; H10W 20/20; H10W 70/65; H10W 90/00; H10W 90/288; H10W 90/291; H10W 90/297; H10W 90/722; H10W 90/792

(57) ABSTRACT

A semiconductor device including a through-via having an improved heat dissipation characteristic and a semiconductor package including the semiconductor device are provided. The semiconductor device includes a semiconductor substrate, an active layer on a lower surface of the semiconductor substrate, a through-via passing through the semiconductor substrate and extending, and a heat dissipation layer including an aluminum nitride (AlN) layer and disposed on an upper surface of the semiconductor substrate to surround a side surface of an upper portion of the through-via.

### CROSS-REFERENCE TO RELATED APPLICATION

This application claims priority to Korean Patent Application No. 10-2024-0147933, filed in the Korean Intellectual Property Office on Oct. 25, 2024, the disclosure of which is incorporated by reference herein in its entirety.

### BACKGROUND

As the electronics industry advances rapidly and the demands of users increases, electronic devices are being smaller and becoming more multifunctional. As electronic devices become smaller and light, semiconductor packages are being smaller and made light with high performance, large capacity, and high reliability. To realize a small size, lightness, high performance, large capacity, and high reliability, semiconductor chips having a through silicon via (TSV) structure and semiconductor packages having a chip stack structure, where the semiconductor chips are stacked, are being researched and developed.

### SUMMARY

In general, in some aspects, the present disclosure is directed toward a semiconductor device comprising a through-via having an improved heat dissipation characteristic and a semiconductor package including the semiconductor device.

According to some implementations, the present disclosure is direct to a semiconductor device comprising a semiconductor substrate, an active layer on a lower surface of the semiconductor substrate, a through-via passing through the semiconductor substrate and extending, and a heat dissipation layer including an AlN layer and disposed on an upper surface of the semiconductor substrate to surround a side surface of an upper portion of the through-via.

According to some implementations, the present disclosure is directed to a semiconductor package comprising a base chip, a plurality of memory chips disposed on the base chip, and a sealant sealing the plurality of memory chips, on the base chip, wherein each of the plurality of memory chips includes a first semiconductor substrate, a first active layer on a lower surface of the first semiconductor substrate, a first through-via passing through the first semiconductor substrate and extending, and a first heat dissipation layer including an aluminum nitride (AlN) layer and disposed on an upper surface of the first semiconductor substrate to surround a side surface of an upper portion of the first through-via.

According to some implementations, the present disclosure is directed to a semiconductor package comprising a package substrate, a first semiconductor device on the package substrate, and at least one second semiconductor device disposed on the package substrate and adjacent to the first semiconductor device, wherein the at least one second semiconductor device includes a base chip, a plurality of memory chips disposed on the base chip, and a sealant sealing the plurality of memory chips, on the base chip, and each of the plurality of memory chips includes a semiconductor substrate, an active layer on a lower surface of the semiconductor substrate, a through-via passing through the semiconductor substrate and extending, and a heat dissipation layer including an AlN layer and disposed on an upper surface of the semiconductor substrate to surround a side surface of an upper portion of the through-via.

### BRIEF DESCRIPTION OF THE DRAWINGS

Example implementations will be more clearly understood from the following detailed description, taken in conjunction with the accompanying drawings.

FIG. 1 is a cross-sectional view of an example of a semiconductor device including a through-via according to some implementations.

FIG. 2 is a cross-sectional view of an example of a semiconductor device including a through-via according to some implementations.

FIGS. 3A to 3D are cross-sectional views of an example of a semiconductor package according to some implementations.

FIGS. 4A and 4B are perspective and cross-sectional views of an example of a semiconductor package according to some implementations.

FIGS. 5A to 5D are cross-sectional views of an example of a system package according to some implementations.

FIGS. 6A to 6G are cross-sectional views schematically illustrating an example of a process of a method of manufacturing a semiconductor device according to some implementations.

### DETAILED DESCRIPTION

Hereinafter, example implementations will be explained in detail with reference to the accompanying drawings. Like reference numerals refer to like elements in the drawings, and their repeated descriptions are omitted.

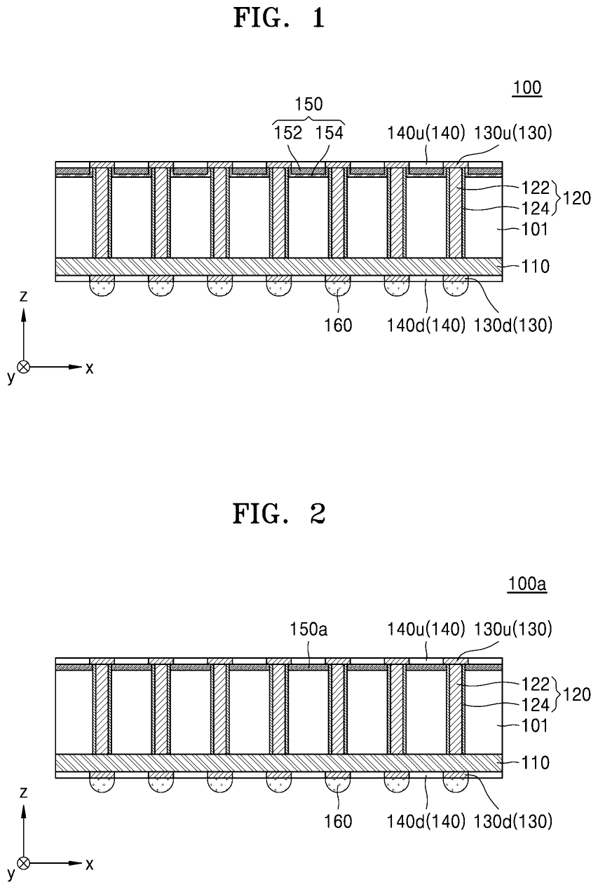

FIG. 1 is a cross-sectional view of an example of a semiconductor device including a through-via according to some implementations. In FIG. 1, a semiconductor device 100 including a through-via (hereinafter simply referred to as a semiconductor device) may include a semiconductor substrate 101, an active layer 110, a through-via 120, a connection pad 130, a passivation layer 140, a heat dissipation layer 150, and a connection terminal 160.

The semiconductor substrate 101 may configure a body of the semiconductor device 100 and may include silicon (Si). However, a material of the semiconductor substrate 101 is not limited to Si. For example, the semiconductor substrate 101 may include a semiconductor material, such as germanium (Ge) or silicon germanium (SiGe), or a compound semiconductor, such as silicon carbide (SiC), gallium phosphide (GsP), gallium arsenide (GaAs), gallium antimony (GaSb), or indium phosphide (InP). In some implementations, the semiconductor substrate 101 may include a silicon-on-insulator (SOI) substrate or a germanium-on-insulator (GOI) substrate. For example, the semiconductor substrate 101 may include a buried oxide layer (BOX) layer.

The active layer 110 may be disposed under the semiconductor substrate 101 and may include an integrated circuit layer and a wiring layer. For example, the integrated circuit layer may include various active devices and/or passive devices, such as transistors, logic devices, memory devices, system large scale integration (LSI), complementary metal-oxide-semiconductor (CMOS) imaging sensor (CIS), and micro-electro-mechanical system (MEMS).

The transistors may include, for example, a field effect transistor (FET), such as FinFET, bipolar junction transistor (BJT), or planar FET. The logic devices may include, for example, an AND gate, a NAND gate, an OR gate, a NOR gate, an XOR gate, an XNOR gate, an inverter (INV), an adder (ADD), a delay (DLY), a filter (FIL), a multiplexer (MXT/MXIT), an OR/AND/INVERTER (OAI) gate, an AND/OR (AO) gate, an AND/OR/INVERTER (AOI), a D flip-flop, a reset flip-flop, a master-slave flip-flop, a latch, a counter, or a buffer. The logic devices may perform various signal processing such as analog signal processing, analog-to-digital (A/D) conversion, and control.

The memory devices may include, for example, flash memory, dynamic random access memory (DRAM), static random access memory (SRAM), electrically erasable programmable read-only memory (EEPROM), phase-change random access memory (PRAM), magnetoresistive random access memory (MRAM), ferroelectric random access memory (FeRAM), and resistive random access memory (RRAM).

In the semiconductor device 100, the integrated circuit layer of the active layer 110 may include a plurality of memory devices. For example, the integrated circuit layer may include a volatile memory device, such as DRAM or SRAM, or a non-volatile memory device such as PRAM, MRAM, FeRAM, or RRAM. In the semiconductor device 100, the integrated circuit layer of the active layer 110 may include DRAM devices. Accordingly, the semiconductor device 100 may be a DRAM chip. Also, the semiconductor device 100 may be a DRAM chip for high bandwidth memory (HBM). However, the semiconductor device 100 is not limited to a DRAM chip or a DRAM chip for HBM.

The wiring layer of the active layer 110 may be disposed under the integrated circuit layer. The wiring layer may connect elements with each other, or may connect the elements to the connection terminal 160. Also, the wiring layer may connect the through-via 120 to the connection terminal 160. The wiring layer may include an interlayer insulation layer and wirings. The wirings may be connected to the elements of the integrated circuit layer, the through-via 120, or the connection terminal 160 through a contact or a via. The wirings may be disposed as two or more layers. Wirings of another layer may be insulated from each other by the interlayer insulation layer and may be connected to each other through a via.

The through-via 120 may pass through the semiconductor substrate 101 and may extend in a vertical direction (i.e., a z direction). In some implementations, the through-via 120 may extend into the active layer 110. The semiconductor substrate 101 may include Si, and thus, the through-via 120 may correspond to a through silicon via (TSV). For reference, the through-via 120 may be distinguished into a via-first structure which is formed before the integrated circuit layer is formed, a via-middle structure which is formed before the wiring layer is formed after the integrated circuit layer is formed, and a via-last structure which is formed after the wiring layer is formed. The semiconductor device 100 may include, for example, the through-via 120 of the via-middle structure. However, the present disclosure is not limited thereto, and the semiconductor device 100 may include the through-via 120 of the via-first structure or the via-last structure.

In FIG. 1, the through-via 120 may have a pillar shape extending in the z direction and may include an electrode layer 122 and an electrode insulation layer 124. The electrode layer 122 may include a barrier layer of an outer surface thereof and a buried conductive layer of an inner portion thereof. The barrier layer may include at least one material selected from among titanium (Ti), titanium nitride (TiN), tantalum (Ta), tantalum nitride (TaN), ruthenium (Ru), cobalt (Co), manganese (Mn), tungsten nitride (WN), nickel (Ni), and nickel boride (NiB). The buried conductive layer may include at least one material selected from among a copper (Cu) alloy such as Cu, copper tin (CuSn), copper magnesium (CuMg), copper nickel (CuNi), copper zinc (CuZn), copper palladium (CuPd), copper gold (CuAu), copper rhenium (CuRc), or copper tungsten (CuW), W, a W alloy, Ni, Ru, and Co. However, materials of the barrier layer and the buried conductive layer are not limited to the materials described above.

Moreover, the electrode insulation layer 124 may have a structure which surrounds an outer side surface of the electrode layer 122. Therefore, the electrode insulation layer 124 may be disposed between the electrode layer 122 and the semiconductor substrate 101 and/or between the electrode layer 122 and the active layer 110. The electrode insulation layer 124 may include, for example, oxide, nitride, carbide, a polymer, or a combination thereof. In the semiconductor device 100, the electrode insulation layer 124 may include, for example, silicon oxide (SiO₂). However, a material of the electrode insulation layer 124 is not limited to SiO₂.

The connection pad 130 may include an upper connection pad 130u and a lower connection pad 130d. The upper connection pad 130u may be disposed on an upper surface of the semiconductor device 100. In FIG. 1, the upper connection pad 130u may be directly connected to the through-via 120. The lower connection pad 130d may be disposed on a lower surface of the semiconductor device 100. The lower connection pad 130d may be connected to the through-via 120 through the wiring layer. The connection pad 130 may include, for example, at least one of aluminum (Al), Cu, Ni, W, platinum (Pt), and gold (Au). In the semiconductor device 100, the connection pad 130 may include Cu. However, a material of the connection pad 130 is not limited to Cu.

The passivation layer 140 may be disposed on a lower surface and an upper surface of the semiconductor device 100. The passivation layer 140 may include a lower passivation layer 140d on the lower surface of the semiconductor device 100 and an upper passivation layer 140u on the upper surface of the semiconductor device 100. In the semiconductor device 100, each of the lower passivation layer 140d and the upper passivation layer 140u may have a multi-layer structure. For example, each of the lower passivation layer 140d and the upper passivation layer 140u may include two or more insulation layers. However, the number of layers of each of the lower passivation layer 140d and the upper passivation layer 140u is not limited to the numerical range. In FIG. 1, for convenience, each of the lower passivation layer 140d and the upper passivation layer 140u is illustrated as a single layer. The passivation layer 140 may include, for example, oxide, nitride, carbide, a polymer, or a combination thereof.

In the semiconductor device 100, the lower surface may be a front-side surface FS which is an active surface, and the upper surface may be a backside surface BS which is an inactive surface. In other words, a lower surface of the wiring layer of the active layer 110 may correspond to the front-side surface FS of the semiconductor device 100, and an upper surface of the semiconductor substrate 101 may correspond to the backside surface BS of the semiconductor device 100. Accordingly, the lower passivation layer 140d and the lower connection pad 130d may be disposed on the front-side surface FS which is the active surface of the semiconductor device 100, and the upper passivation layer 140u and the upper connection pad 130u may be disposed on the backside surface BS which is the inactive surface of the semiconductor device 100.

Furthermore, the lower connection pad 130d may be disposed in a structure which passes through at least a portion of the lower passivation layer 140d. For example, the lower connection pad 130d may have a structure which completely passes through the lower passivation layer 140d, or passes through a portion of the lower passivation layer 140d. The lower connection pad 130d may have a structure which is buried in the lower passivation layer 140d and may be exposed from a lower surface of the lower passivation layer 140d. The lower connection pad 130d may be connected to the wirings of the wiring layer of the active layer 110. Also, the lower connection pad 130d may be connected to the through-via 120 through the wirings of the wiring layer.

The upper connection pad 130u may be disposed in a structure which passes through at least a portion of the upper passivation layer 140u. For example, the upper connection pad 130u may have a structure which completely passes through the upper passivation layer 140u, or passes through a portion of the upper passivation layer 140u. The upper connection pad 130u may have a structure which is buried in the upper passivation layer 140u and may be exposed from an upper surface of the upper passivation layer 140u. The upper connection pad 130u may be directly connected to the through-via 120. That is, a lower surface of the upper connection pad 130u may contact an upper surface of the through-via 120.

The heat dissipation layer 150 may be disposed on the semiconductor substrate 101, under the upper passivation layer 140u. The heat dissipation layer 150 may cover the upper surface of the semiconductor substrate 101 and a side surface of an upper portion of the through-via 120. The heat dissipation layer 150 may include an aluminum nitride (AlN) layer 152 and a lower insulation layer 154. The lower insulation layer 154 may include a bottom portion covering the upper surface of the semiconductor substrate 101 and a sidewall portion covering a side surface of an upper portion of the through-via 120. The lower insulation layer 154 may include oxide. For example, the lower insulation layer 154 may include SiO₂. However, a material of the lower insulation layer 154 is not limited to oxide.

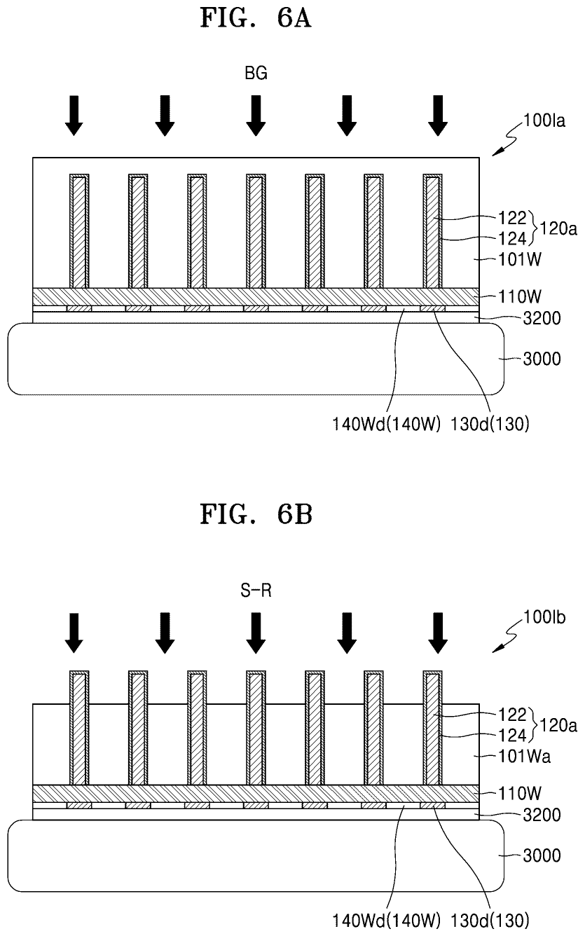

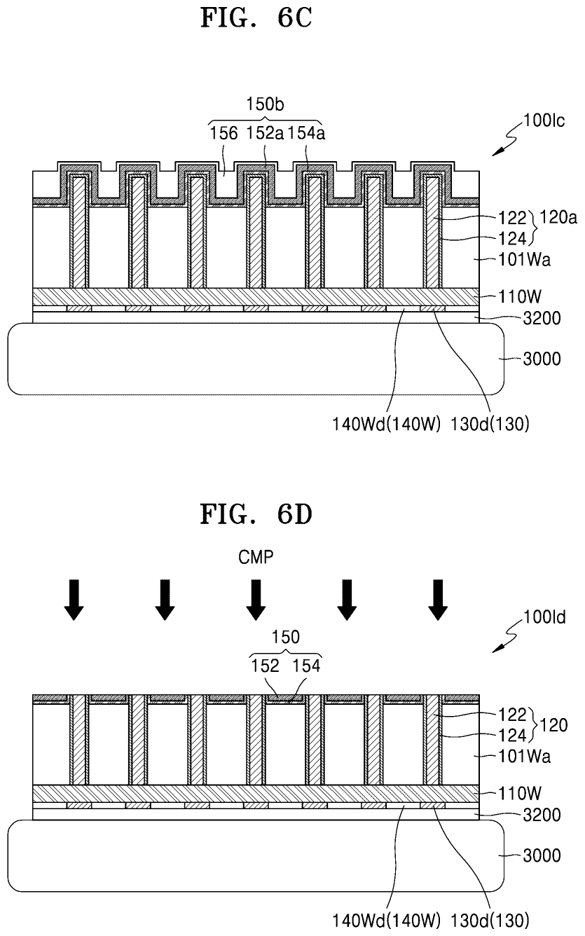

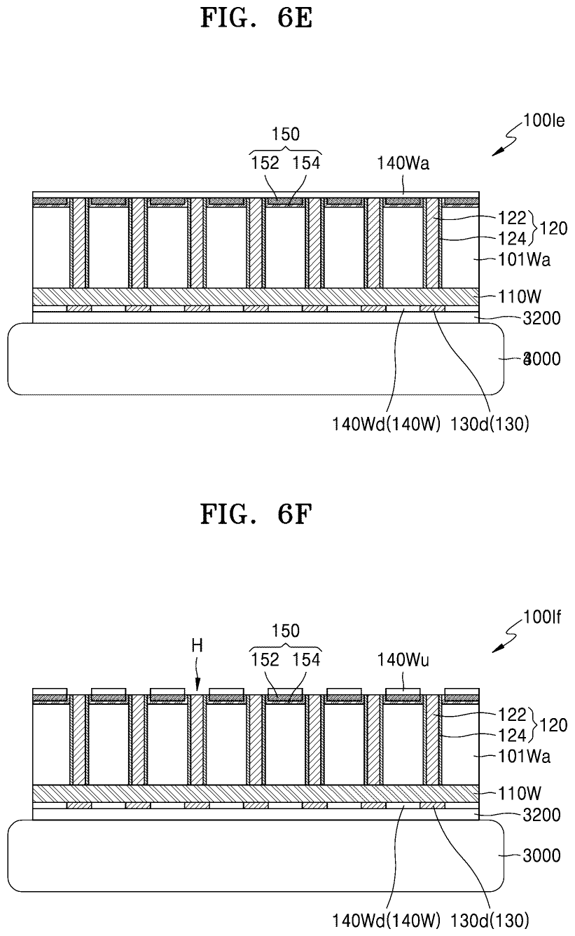

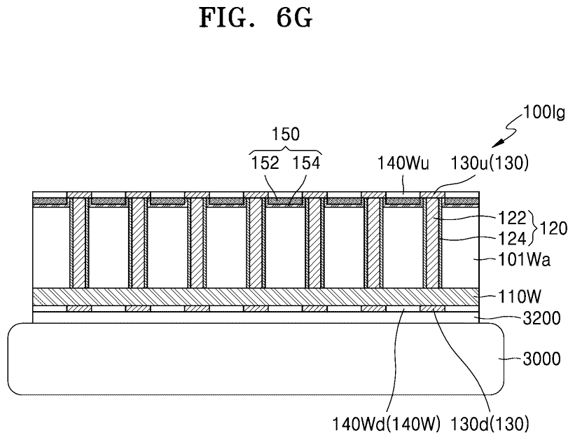

The AlN layer 152 may be disposed on the lower insulation layer 154. The AlN layer 152 may have a shape which fills a concave portion of the lower insulation layer 154. Also, an upper surface of the heat dissipation layer 150 and an upper surface of the through-via 120 may substantially configure a coplanar surface. A shape of each of the AlN layer 152 and the lower insulation layer 154 may be caused in a process of forming the AlN layer 152 and the lower insulation layer 154. A process of forming the AlN layer 152 and the lower insulation layer 154 may be described in more detail in describing a method of manufacturing a semiconductor device illustrated in FIGS. 6A to 6G. The AlN layer 152, as seen in the term, may include AlN. Therefore, the AlN layer 152 may have a high thermal conductance, based on a characteristic of AlN. For example, AlN may maximally have a thermal conductance of about 803 W/m·K, based on the adjustment of a process condition. For reference, SiO₂ may have a thermal conductance of about 1.3 W/m·K, and SiN may have a thermal conductance of about 43 W/m·K.

The connection terminal 160 may be disposed on the lower surface of the semiconductor device 100. In detail, the connection terminal 160 may be disposed on the lower connection pad 130d of the lower surface of the semiconductor device 100. The connection terminal 160 may include a solder. The solder may include tin (Sn), indium (In), bismuth (Bi), antimony (Sb), Cu, silver (Ag), zinc (Zn), and/or an alloy thereof. For example, the solder may include Sn, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, or Sn—Bi—Zn. In some embodiments, the connection terminal 160 may be referred to as a bump, a solder, or a solder bump.

In some implementations, the connection terminal 160 may further include a pillar, and the solder may be disposed on the pillar. The pillar may include, for example, Ni, Cu, Pd, Pt, Au, or an alloy thereof. In some implementations, the pillar may function as a chip pad and may include Cu. Accordingly, the pillar may be referred to as a bump pad, a Cu-pad, or a Cu-pillar. In a case where the pillar functions as a chip pad, a chip pad (for example, the lower connection pad 130d) on the lower surface of the semiconductor device 100 may not be formed.

In the semiconductor device 100, the heat dissipation layer 150 including the AlN layer 152 may be provided on the backside surface of the semiconductor substrate 101, and heat occurring in the semiconductor device 100 may be efficiently dissipated to the outside through the heat dissipation layer 150. Accordingly, in the semiconductor device 100, a reduction in characteristic caused by the occurrence of heat may be effectively reduced. Also, in the semiconductor device 100, the AlN layer 152 may be formed to have a uniform thickness through an atomic layer deposition (ALD) process, and thus, a profile of the AlN layer 152 on the backside surface of the semiconductor substrate 101 may be easily controlled in a chemical mechanical polishing (CMP) process. Also, the AlN layer 152 may be better in selectivity than a SiN layer with respect to a SiO₂ layer, and may have a thickness which is thinner than that of the SiN layer and may be used as a stop layer.

Furthermore, the AlN layer 152 is not limited to the ALD process and may be formed by a physical vapor deposition (PVD) process or a chemical vapor deposition (CVD) process. The AlN layer 152 may have stress of 0 to (−) 1.5 GPa, based on the adjustment of a process condition. Here, (−) may denote compression stress. However, the stress of the AlN layer 152 is not limited to the numerical range.

FIG. 2 is a cross-sectional view of an example of a semiconductor device including a through-via according to some implementations. Descriptions, which are the same as or similar to the descriptions of FIG. 1, will be briefly given below or are omitted.

In FIG. 2, in a structure of a heat dissipation layer 150a, a semiconductor device 100a may differ from the semiconductor device 100 of FIG. 1. In detail, the semiconductor device 100a may include a semiconductor substrate 101, an active layer 110, a through-via 120, a connection pad 130, a passivation layer 140, the heat dissipation layer 150a, and a connection terminal 160. The semiconductor substrate 101, the active layer 110, the through-via 120, the connection pad 130, the passivation layer 140, and the connection terminal 160 may be the same as the descriptions of FIG. 1.

In the semiconductor device 100a, the heat dissipation layer 150a may include a single AlN layer and may not include a lower insulation layer. Accordingly, the heat dissipation layer 150a of the single AlN layer may directly cover a backside surface of the semiconductor substrate 101 and an upper side surface of the through-via 120. The single AlN layer may be the same as the description of the AlN layer 152 of the heat dissipation layer 150 of FIG. 1. Because the semiconductor device 100a includes the heat dissipation layer 150a of the single AlN layer, heat occurring in the semiconductor device 100a may be efficiently dissipated to the outside through the heat dissipation layer 150a. Accordingly, in the semiconductor device 100a, a reduction in characteristic caused by the occurrence of heat may be effectively reduced.

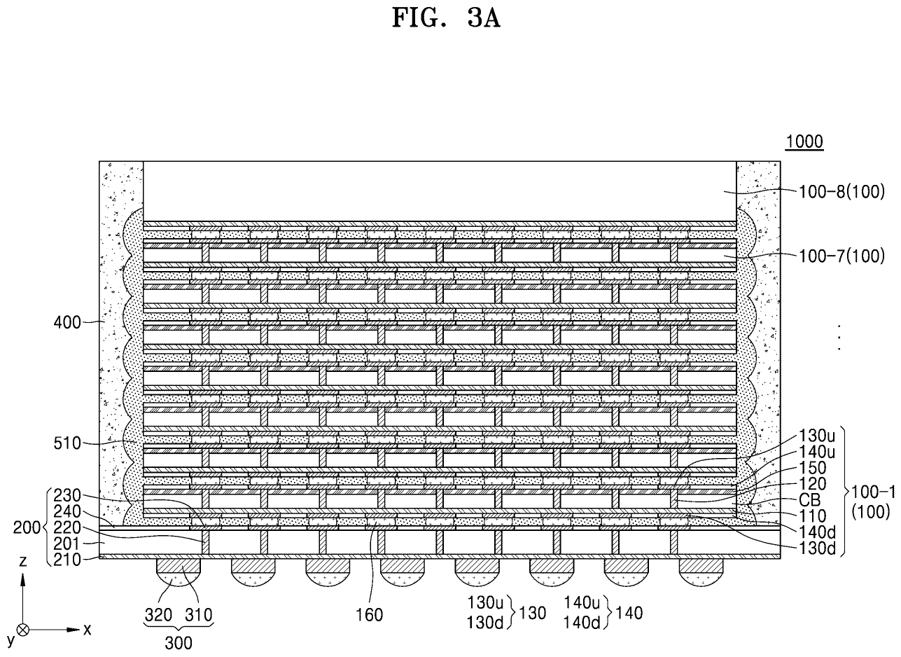

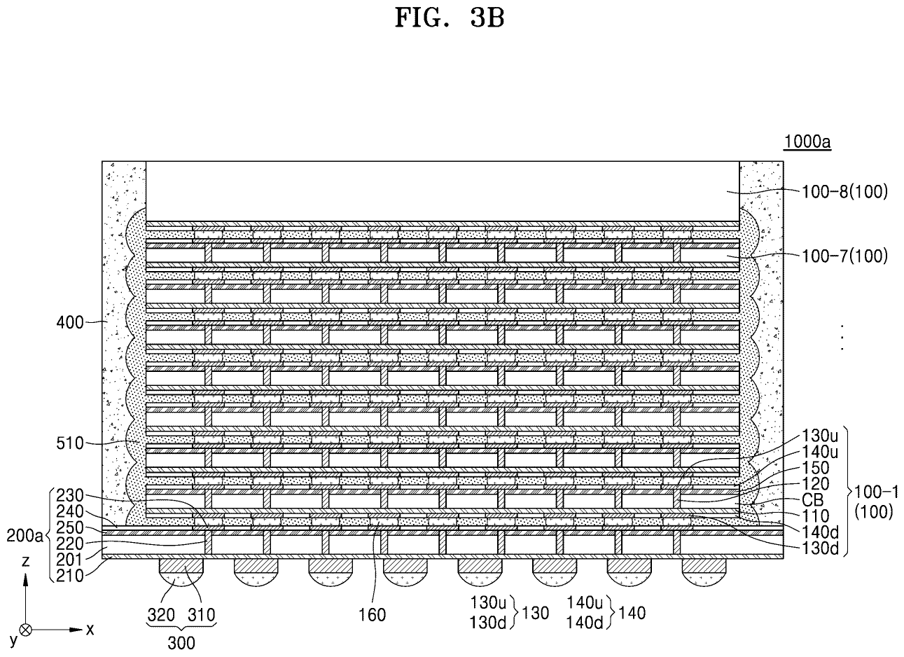

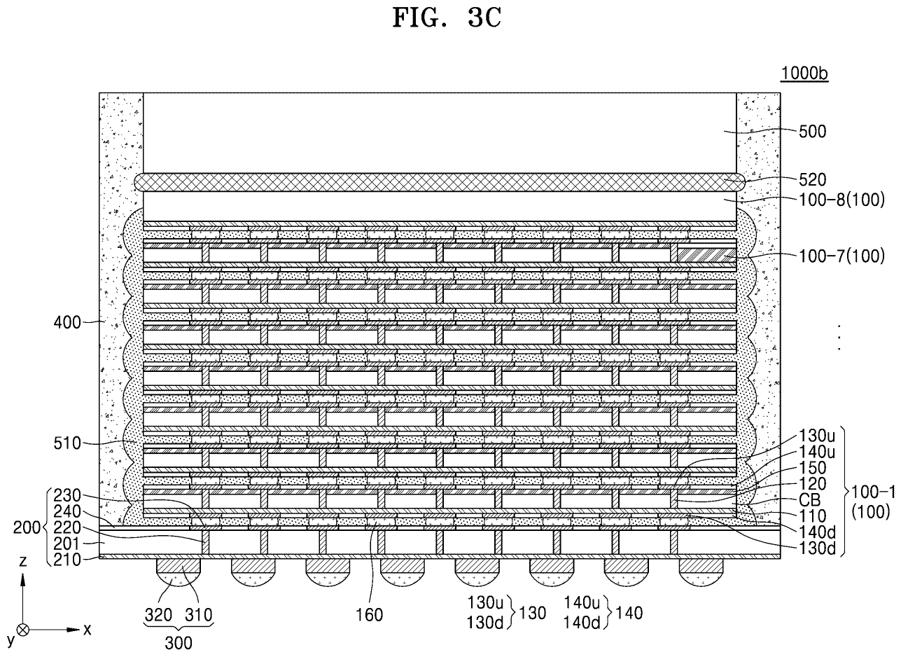

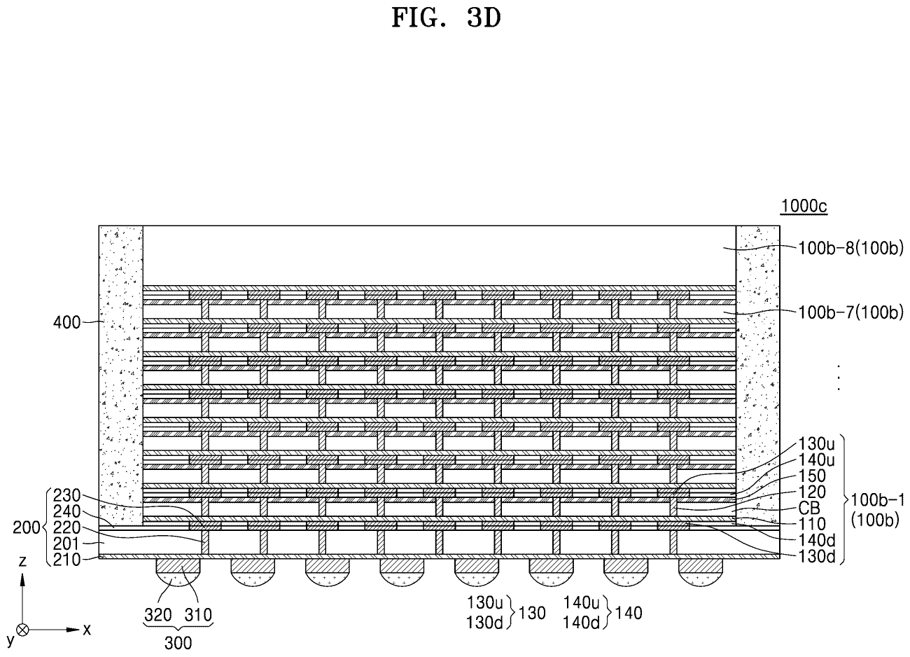

FIGS. 3A to 3D are cross-sectional views of an example of a semiconductor package according to some implementations. FIGS. 3A to 3D may be described with reference to FIG. 1, and descriptions which are the same as or similar to the descriptions of FIGS. 1 and 2 will be briefly given below or are omitted.

IN FIG. 3A, a semiconductor package 1000 may include memory chips 100, a base chip 200, a first external connection terminal 300, and a sealant 400.

In the semiconductor package 1000, each of the memory chips 100 may include the semiconductor device 100 of FIG. 1. Accordingly, each of the memory chips 100 may include a heat dissipation layer 150 including an AlN layer 152. However, each of the memory chips 100 is not limited to the semiconductor device 100 of FIG. 1. For example, each of the memory chips 100 may include the semiconductor device 100a of FIG. 2. In FIG. 3A and the following drawings, for convenience, the heat dissipation layer 150 is illustrated as a single layer.

The memory chips 100 may be stacked on the base chip 200. In the semiconductor package 1000, eight memory chips 100 (for example, first to eighth memory chips 100-1 to 100-8) may be stacked on the base chip 200. However, the number of memory chips 100 stacked on the base chip 200 is not limited to eight. For example, two to seven, or nine or more memory chips 100 may be stacked on the base chip 200.

For reference, in the semiconductor package 1000, the number of memory chips 100 may be a 4n (where n may be a natural number) number. Accordingly, the semiconductor package 1000 may include a four-multiple number of memory chips, such as four, eight, and twelve memory chips. Also, four memory chips 100 each may have the same stack-identification (ID), and moreover, may be tested and operate together. For example, when the semiconductor package 1000 includes eight memory chips 100, the first to fourth memory chips 100-1 to 100-4 may have a first stack-ID, and the fifth to eighth memory chips 100-5 to 100-8 may have a second stack-ID. However, the semiconductor package 1000 is not limited to a four-multiple number of memory chips 100 and a stack-ID corresponding thereto. For example, the semiconductor package 1000 may include a two-multiple number of memory chips 100 and a stack-ID corresponding thereto, or may include an eight-multiple number of memory chips 100 and a stack-ID corresponding thereto.

The memory chips 100 may have the same horizontal size and internal structure. However, the eighth memory chip 100-8 disposed at an uppermost portion may not include a through-via. Also, as illustrated in FIG. 3A, the eighth memory chip 100-8 may have a thickness which is thicker than that of each of the other memory chips 100. In some implementations, a thickness of the eighth memory chip 100-8 may be adjusted, and a total height of the semiconductor package 1000 may be adjusted.

In the semiconductor package 1000, the memory chips 100 may be stacked on the base chip 200 or a memory chip 100 thereunder through the connection terminal 160. For example, a connection terminal 160 may be disposed between a connection pad 230 of the base chip 200 and a lower connection pad 130d of the first memory chip 100-1. Also, the connection terminal 160 may be disposed between an upper connection pad 130u of a lower memory chip 100 and a lower connection pad 130d of an upper memory chip 100, in two memory chips 100 adjacent to each other.

In the semiconductor package 1000, as the memory chips 100 are stacked through the connection terminal 160, an adhesive layer 510 may be disposed between the base chip 200 and the first memory chip 100-1 and between two memory chips 100 adjacent to each other. For example, the adhesive layer 510 may be filled between the base chip 200 and the first memory chip 100-1 and between two memory chips 100 adjacent to each other and may cover a side surface of each of the connection terminals 160. Also, as illustrated in FIG. 3A, the adhesive layer 510 may protrude from a side surface of each of the memory chips 100 and may cover the side surface of each of the memory chips 100. Moreover, in some implementations, the adhesive layer 510 may protrude from the side surface of each of the memory chips 100 and may cover only a portion of the side surface of each of the memory chips 100. In this case, an upper adhesive layer 510 and a lower adhesive layer 510 may not be adhered to each other and may be apart from each other on the side surface of each of the memory chips 100.

The adhesive layer 510 may include, for example, a non-conductive film (NCF). The NCF, for example, may be used as an adhesive layer in a case where semiconductor chips are bonded to each other by a thermal compression bonding (TCB) process, in a semiconductor chip stack process. However, a material of the adhesive layer 510 is not limited to the NCF.

In the semiconductor package 1000, each of the memory chips 100 may include a DRAM chip. Also, each of the memory chips 100 may include a DRAM chip for HBM. Accordingly, the semiconductor package 1000 according to an embodiment may be an HBM package. However, the semiconductor package 1000 is not limited to the HBM package.

The base chip 200 may be disposed under the memory chips 100. The base chip 200, as illustrated in FIG. 3A, may have a size which is greater than that of each of memory chips 100 disposed at an upper portion. However, a size of the base chip 200 is not limited thereto. For example, in some implementations, the base chip 200 may have substantially the same size as that of each of the memory chips 100.

The base chip 200 may include a semiconductor substrate 201, an active layer 210, a through-via 220, a connection pad 230, and a passivation layer 240. The semiconductor substrate 201, the active layer 210, the through-via 220, the connection pad 230, and the passivation layer 240 may be the same as the descriptions of the semiconductor substrate 101, the active layer 110, the through-via 120, the connection pad 130, and the passivation layer 140 of the semiconductor device 100 of FIG. 1.

In the base chip 200, an integrated circuit layer of the active layer 110 may include a plurality of logic devices. Accordingly, the base chip 200 may be a logic chip. The base chip 200 may be disposed under the memory chips 100 and may integrate signals from the memory chips 100 to transfer an integrated signal to the outside, and moreover, may transfer a signal and power from the outside to the memory chips 100. Accordingly, the base chip 200 may be referred to as a buffer chip or an interface chip. For reference, when the base chip 200 is referred to as a buffer chip, the memory chips 100 may be referred to as a core chip.

In some implementations, the base chip 200 may include a controller that controls signal transfer between the memory chips 100 and an external device. When the base chip 200 includes the controller, the base chip 200 may be referred to as a logic chip or a control chip. Also, in some implementations, the base chip 200 may include a power management integrated circuit (PMIC) which manages power or a clock.

In the semiconductor package 1000, the base chip 200 is not limited to the buffer chip or the logic chip. For example, the base chip 200 may include a plurality of memory devices which are in the integrated circuit layer of the active layer 210. Accordingly, the base chip 200 may include a memory chip.

In the semiconductor package 1000 of FIG. 3A, the connection pad 230 and the passivation layer 240 may respectively correspond to the upper connection pad 130u and the upper passivation layer 140u of the semiconductor device 100 of FIG. 1. Also, the base chip 200 may include a lower connection pad and a lower passivation layer. However, in FIG. 3A and the following drawings, the first external connection terminal 300 is illustrated to be relatively large.

The first external connection terminal 300 may be disposed on a lower surface of the base chip 200. The first external connection terminal 300 may be connected to wirings of a wiring layer of the active layer 210 of the base chip 200. Also, the first external connection terminal 300 may be connected to the through-via 220 through the wirings of the wiring layer. Although not shown, a chip pad may be disposed on a lower surface of the base chip 200, and the first external connection terminal 300 may be disposed on the chip pad. Here, the chip pad may correspond to a lower connection pad.

The first external connection terminal 300 may include a pillar 310 and a solder 320. The pillar 310 may have a circular pillar shape. A material of the pillar 310 may be the same as the description of the pillar of the connection terminal 160. In some implementations, the pillar 310 may function as the chip pad of the base chip 200 and may include Cu. Accordingly, the pillar 310 may be referred to as a bump pad, a Cu-pad, or a Cu-pillar. In a case where the pillar 310 functions as the chip pad, a separate chip pad may not be formed on the lower surface of the base chip 200.

The solder 320 may be disposed on the pillar 310 and may have a semispherical shape. A material of the solder 320 may be the same as the description of the solder of the connection terminal 160. In some implementations, the solder 320 may be referred to as a bump or a solder bump. Also, a middle layer may be formed in a contact interface between the pillar 310 and the solder 320. The middle layer may include an inter-metallic compound (IMC) which is formed through a reaction between metal materials included in the pillar 310 and the solder 320 at a relatively high temperature.

The sealant 400 may seal the memory chips 100 on the base chip 200. In detail, the sealant 400 may cover side surfaces of the memory chips 100 on the base chip 200 and/or the adhesive layer 510 protruding to the side surfaces of the memory chips 100. Moreover, as illustrated in FIG. 3A, the sealant 400 may not cover an upper surface of an uppermost memory chip (for example, the eighth memory chip 100-8). Accordingly, the upper surface of the eighth memory chip 100-8 may be exposed from the sealant 400. On the other hand, in some implementations, the sealant 400 may cover the upper surface of the uppermost memory chip (for example, the eighth memory chip 100-8). The sealant 400 may include, for example, an epoxy mold compound (EMC). However, a material of the sealant 400 is not limited to the EMC.

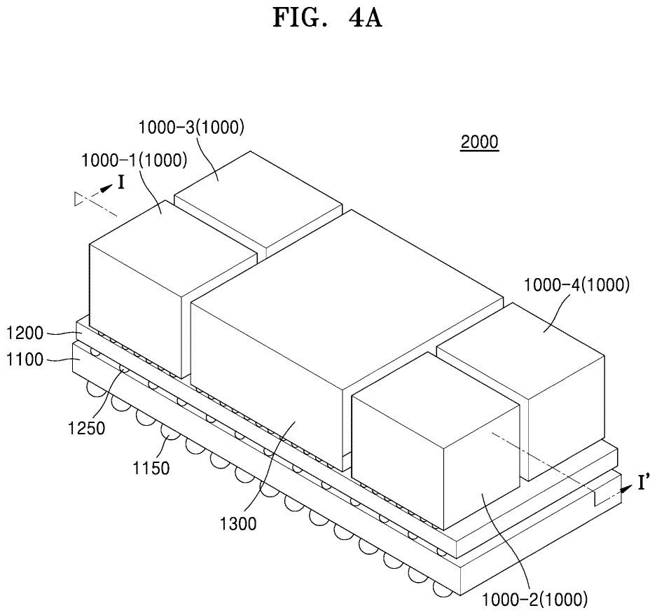

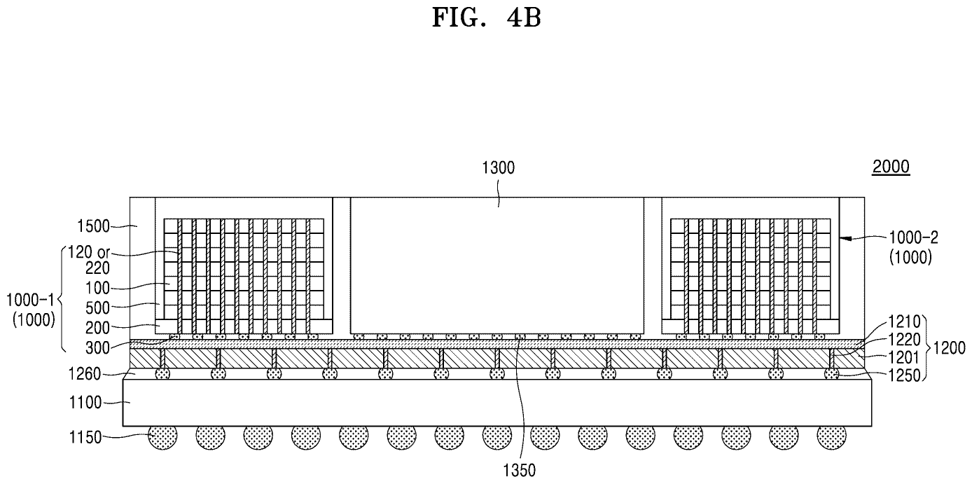

In the semiconductor package 1000, each of the memory chips 100 may include a heat dissipation layer 150 including an AlN layer 152. Accordingly, heat occurring in the semiconductor chips 100 may be efficiently dissipated to the outside through the heat dissipation layer 150. As a result, the semiconductor package 1000 may effectively decrease a reduction in characteristic of the memory chips 100 caused by the occurrence of heat, and thus, a semiconductor package having enhanced reliability and a product or a system package (see 2000 of FIG. 4A) including the semiconductor package may be implemented.

In FIG. 3B, in a structure of a base chip 200a, a semiconductor package 1000a may differ from the semiconductor package 1000 of FIG. 3A. In detail, the semiconductor package 1000a may include memory chips 100, a base chip 200a, a first external connection terminal 300, and a sealant 400. The memory chips 100, the first external connection terminal 300, and the sealant 400 may be the same as the descriptions of the semiconductor package 1000 of FIG. 3A.

In the semiconductor package 1000a, the base chip 200a may include a semiconductor substrate 201, an active layer 210, a through-via 220, a connection pad 230, a passivation layer 240, and a heat dissipation layer 250. The semiconductor substrate 201, the active layer 210, the through-via 220, the connection pad 230, and the passivation layer 240 may be the same as the descriptions of the base chip 200 of the semiconductor package 1000 of FIG. 3A. Also, the heat dissipation layer 250 may be the same as the description of the heat dissipation layer 150 of the semiconductor device 100 of FIG. 1.

In the semiconductor package 1000a, because the base chip 200a includes the heat dissipation layer 250, heat occurring in the base chip 200a may be efficiently dissipated to the outside through the heat dissipation layer 250. Furthermore, in the semiconductor package 1000a, a structure of the heat dissipation layer 150a of the semiconductor device 100a of FIG. 2 instead of a structure of the heat dissipation layer 150 of the semiconductor device 100 of FIG. 1 may be applied to the heat dissipation layer 250.

In the semiconductor package 1000a, the memory chips 100 and the base chip 200a may respectively include heat dissipation layers 150 and 250 respectively including AlN layers 152 and 252. Accordingly, heat occurring in the semiconductor chips 100 and the base chip 200a may be efficiently dissipated to the outside through the heat dissipation layers 150 and 250. As a result, the semiconductor package 1000a may effectively decrease a reduction in characteristic of the memory chips 100 and the base chip 200a caused by the occurrence of heat, and thus, a semiconductor package having enhanced reliability and a product or a system package (see 2000 of FIG. 4A) including the semiconductor package may be implemented.

In FIG. 3C, a semiconductor package 1000b may further include a top dummy chip 500, and may differ from the semiconductor package 1000 of FIG. 3A. In detail, the semiconductor package 1000b may include memory chips 100, a base chip 200, a first external connection terminal 300, a sealant 400, and a top dummy chip 500. The memory chips 100, the base chip 200, the first external connection terminal 300, and the sealant 400 may be the same as the descriptions of the semiconductor package 1000 of FIG. 3A. Also, as the top dummy chip 500 is added, the sealant 400 may have a structure which covers a side surface of the top dummy chip 500.

In the semiconductor package 1000b, the top dummy chip 500 may be stacked on the memory chips 100 through an adhesive layer 520. The top dummy chip 500 may be added for conforming with a height standard of the semiconductor package 1000b. For example, in an HBM package, a height and an area may be defined according to Joint Electron Device Engineering Council (JEDEC) standard, and when the semiconductor package 1000b is an HBM package, as the top dummy chip 500 having an appropriate height is disposed on the memory chips 100, a height of the semiconductor package 1000b may conform with JEDEC standard.

In the semiconductor package 1000b, as the top dummy chip 500 is added, an eighth memory chip 100-8 may have a thickness which is similar to that of each of the other memory chips 100. However, the present disclosure is not limited thereto, and in some implementations, even when the top dummy chip 500 is provided, the eighth memory chip 100-8 may have a thickness which is thicker than that of each of the other memory chips 100. On the other hand, in a case where a total height of a semiconductor package is adjusted by adjusting a height of the eighth memory chip 100-8, the top dummy chip 500 may be omitted.

In FIG. 3D, a semiconductor package 1000c may include memory chips 100b which are stacked through hybrid copper bonding (HCB), and may differ from the semiconductor package 1000 of FIG. 3A. In detail, the semiconductor package 1000c may include memory chips 100b, a base chip 200, a first external connection terminal 300, and a sealant 400. The base chip 200, the first external connection terminal 300, and the sealant 400 may be the same as the descriptions of the semiconductor package 1000 of FIG. 3A. Because the memory chips 100b are stacked through HCB without a connection terminal 160, an adhesive layer which is not filled between the memory chip 100b and the base chip 200 and between adjacent memory chips 100b may not be provided.

In the semiconductor package 1000c, the memory chips 100b may be stacked on the base chip 200 or a lower memory chip 100b through HCB. Also, the memory chips 100b may be stacked on the base chip 200 or a lower memory chip 100b through a TCB process. Here, HCB may denote a bonding process where a pad-to-pad bonding process and an insulator-to-insulator bonding process are combined. Furthermore, because a pad is generally formed of Cu, the pad-to-pad bonding process may be referred to as a Cu-to-Cu bonding process.

To provide a detailed description, as described above, a connection pad 230 and a passivation layer 240 may be disposed on an upper surface of the base chip 200. Also, a connection pad 130 and a passivation layer 140 may be disposed on a lower surface and an upper surface of each of the memory chips 100b. The connection pad 230 of the base chip 200 may be disposed in a buried structure in the passivation layer 240, and an upper surface of the connection pad 230 may be exposed from the passivation layer 240. Also, the connection pad 130 of the memory chip 100b may be disposed in a buried structure in the passivation layer 140, and an upper surface or a lower surface of the connection pad 130 may be exposed from the passivation layer 240. The passivation layers 140 and 240 may include, for example, an insulation layer such as SiO₂ or SiN.

The connection pad 230 of the base chip 200 may be bonded to a lower connection pad 130d of a first memory chip 100b-1, and the passivation layer 240 of the base chip 200 may be bonded to a lower passivation layer 140d of the first memory chip 100b-1, and HCB may be formed between the base chip 200 and the first memory chip 100b-1. Moreover, in the memory chips 100b, an upper connection pad 130u and an upper passivation layer 140u on an upper surface of a lower memory chip 100b may be respectively bonded to a lower connection pad 130d and a lower passivation layer 140d on a lower surface of the lower memory chip 100b, between two adjacent memory chips 100b, and HCB may be formed.

FIGS. 4A and 4B are perspective and cross-sectional views of an example of a semiconductor package according to some implementations. FIG. 4B may correspond to a cross-sectional view taken along line I-I′ of FIG. 4A. FIGS. 4A and 4B may be described with reference to FIG. 1, and descriptions which are the same as or similar to the descriptions of FIGS. 1 to 3D will be briefly given below or are omitted.

In FIGS. 4A and 4B, a system package may include a semiconductor package 1000, a package substrate 1100, an interposer 1200, a first semiconductor device 1300, and an external sealant 1500.

In FIG. 4A, the semiconductor package 1000 may include first to fourth semiconductor packages 1000-1 to 1000-4. For example, two semiconductor packages 1000 may be disposed on the interposer 1200 at each of both sides of the first semiconductor device 1300 through a first external connection terminals 300. However, in the system package 2000, the number of semiconductor packages 1000 is not limited to four. For example, one to three, or five or more semiconductor packages 1000 may be disposed on the interposer 1200.

The semiconductor package 1000 may be, for example, the semiconductor package 1000 of FIG. 3A. Accordingly, the semiconductor package 1000 may include memory chips 100, a base chip 200, a first external connection terminal 300, and a sealant 400. Also, each of the memory chips 100 may include a heat dissipation layer 150. In FIG. 4B, the semiconductor package 1000 is illustrated to be reduced, and for convenience, a connection pad, a passivation layer, a connection terminal an adhesive layer, and the heat dissipation layer are not illustrated.

In the system package 2000, the semiconductor package 1000 may be an HBM package. Accordingly, the base chip 200 of the semiconductor package 1000 may be a buffer chip, and each of the memory chips 100 may be a DRAM chip. However, the semiconductor package 1000 is not limited to the HBM package. Also, the semiconductor package 1000 is not limited to the semiconductor package 1000 of FIG. 3A. For example, the semiconductor packages 1000a to 1000c of FIG. 3A to 3D instead of the semiconductor package 1000 of FIG. 3A may be applied to the system package 2000.

The package substrate 1100 may be a supporting substrate, and the interposer 1200, the semiconductor package 1000, and the first semiconductor device 1300 may be stacked on the package substrate 1100. The package substrate 1100 may internally include a wiring line of at least one layer. In a case where the wiring line is formed of a multilayer, wiring lines of another layer may be connected to each other through a vertical via. The package substrate 1100 may be formed based on, for example, a ceramic substrate, a printed circuit board (PCB), a glass substrate, or an interposer substrate. A second external connection terminal 1150 may be disposed on a lower surface of the package substrate 1100. The system package 2000 may be stacked on an external system substrate or a main board through the second external connection terminal 1150.

The interposer 1200 may include an interposer substrate 1201, a wiring layer 1210, a through-via 1220, and a third external connection terminal 1250. The semiconductor package 1000 and the first semiconductor device 1300 may be mounted on the package substrate 1100 by using the interposer 1200. The interposer 1200 may connect the semiconductor package 1000 to the first semiconductor device 1300. Also, the interposer 1200 may connect the semiconductor package 1000 and the first semiconductor device 1300 to the package substrate 1100.

The interposer substrate 1201 may include, for example, Si. Accordingly, the interposer 1200 may be a Si-interposer. The through-via 1220 may pass through the interposer substrate 1201 and may extend. Because the interposer substrate 1201 includes Si, the through-via 1220 may correspond to a TSV. The through-via 1220 may extend to the wiring layer 1210 and may be connected to wirings of the wiring layer 1210. According to some implementations, the interposer 1200 may internally include only a wiring layer and may not include a through-via. The wiring layer 1210 may be disposed on an upper surface or a lower surface of the interposer substrate 1201. For example, a position relationship between the wiring layer 1210 and the through-via 1220 may be relative. A pad on an upper surface of the interposer 1200 may be connected to the through-via 1220 through the wiring layer 1210.

The third external connection terminal 1250 may be disposed on a lower surface of the interposer 1200 and may be connected to the through-via 1220. The interposer 1200 may be mounted on the package substrate 1100 through the third external connection terminal 1250. The third external connection terminal 1250 may be connected to the pad on the upper surface of the interposer 1200 through wirings of the wiring layer 1210 and the through-via 1220.

In the system package 2000, the interposer 1200 may be used for converting or transferring an electrical signal between the semiconductor package 1000 and the first semiconductor device 1300. Accordingly, the interposer 1200 may not include devices such as an active device or a passive device. However, in some implementations, the interposer 1200 may include devices for controlling signal transfer. Furthermore, an underfill 1260 may be filled between the interposer 1200 and the package substrate 1100 and between third external connection terminals 1250. In some implementations, the underfill 1260 may be replaced with an adhesive layer or an adhesive film.

The first semiconductor device 1300 may be stacked on a center portion of the interposer 1200 through a fourth external connection terminal 1350. The first semiconductor device 1300 may have a chip or package structure. In the system package 2000, the first semiconductor device 1300 may have the chip structure. For example, the first semiconductor device 1300 may include a logic chip. The first semiconductor device 1300 may include a plurality of logic devices. The logic devices may include, for example, an AND gate, a NAND gate, an OR gate, a NOR gate, an XOR gate, an XNOR gate, an inverter (INV), an adder (ADD), a delay (DLY), a filter (FIL), a multiplexer (MXT/MXIT), an OR/AND/INVERTER (OAI) gate, an AND/OR (AO) gate, an AND/OR/INVERTER (AOI), a D flip-flop, a reset flip-flop, a master-slave flip-flop, a latch, a counter, or a buffer. The logic devices may perform various signal processing, such as analog signal processing, analog-to-digital (A/D) conversion, and control. The first semiconductor device 1300 may be referred to as a central processing unit (CPU) chip, a system on glass (SOG) chip, a microprocessor unit (MPU) chip, a graphics processing chip (GPU) chip, a neural processing unit (NPU) chip, an application processor (AP) chip, or a control chip, based on a function thereof.

In the system package 2000, the first semiconductor device 1300 may have the chip structure and may have a system on chip (SoC) structure or a chiplet structure. The SoC structure may have a structure where several systems are integrated into one chip. Accordingly, the first semiconductor device 1300 having the SoC structure may perform an operational function, the storage of data, and analog and digital signal conversion in one chip. The chiplet structure may have a structure where the logic chip is divided into separate chips, and the chips are connected to each other. The first semiconductor device 1300 having the chiplet structure may overcome a performance limitation of a single chip.

The external sealant 1500 may cover and seal the first semiconductor device 1300 and the semiconductor package 1000, on the interposer 1200. As illustrated in FIG. 4B, the external sealant 1500 may not cover an upper surface of each of the first semiconductor device 1300 and the semiconductor package 1000. On the other hand, in some implementations, the external sealant 1500 may cover the upper surface of at least one of the first semiconductor device 1300 and the semiconductor package 1000. In the system package 2000, a second external sealant covering and sealing the interposer 1200 and the external sealant 1500 may be further provided on the package substrate 1100.

For reference, a structure of the system package 2000 may be referred to as a 2.5-dimensional (2.5D) package structure, and the 2.5D package structure may be a relative concept of a three-dimensional (3D) package structure where all semiconductor chips are stacked, and there is no interposer. The 2.5D package structure and the 3D package structure may be included in a system in package (SIP) structure. Furthermore, the system package 2000 may be included in a semiconductor package and may be referred to as a system package for terminological differentiating from the semiconductor package 1000 which is an element.

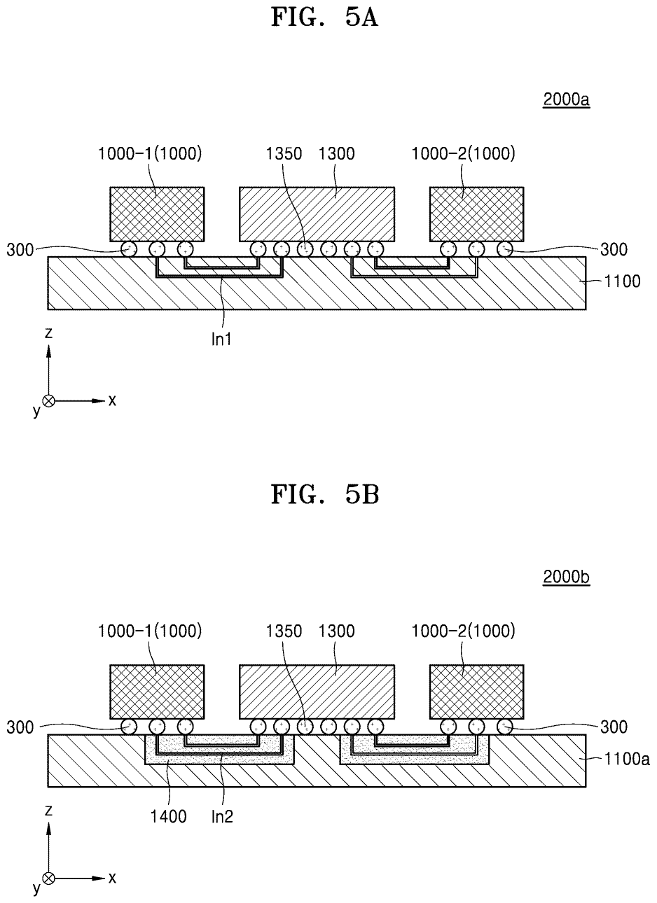

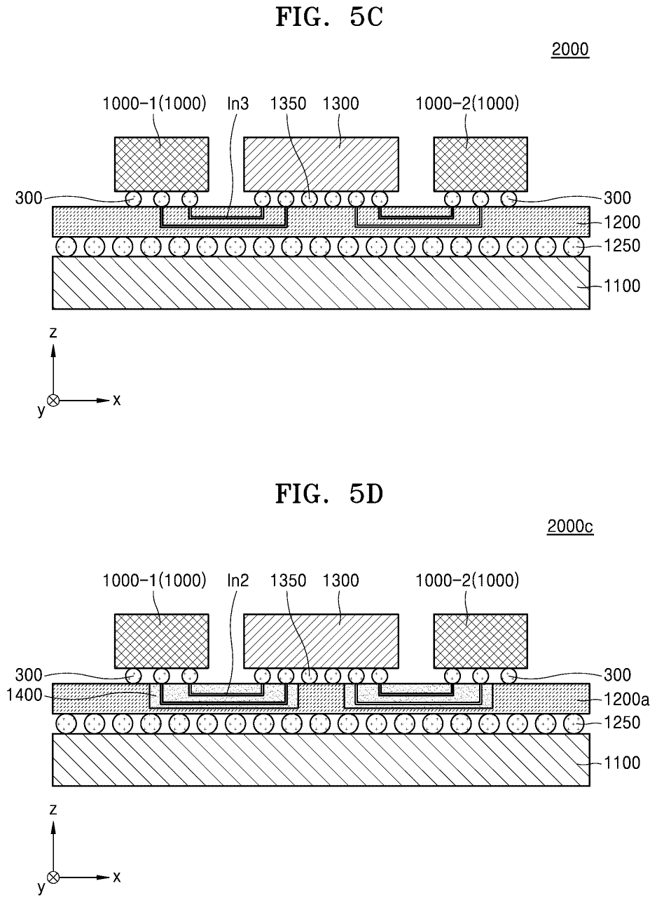

FIGS. 5A to 5D are cross-sectional views of an example of a system package according to some implementations. Descriptions, which are the same as or similar to the descriptions of FIGS. 1 to 4B, will be briefly given below or are omitted. For reference, FIGS. 5A to 5D are cross-sectional views corresponding to FIG. 4B, and in terms of a connection structure between a semiconductor package 1000 and a first semiconductor device 1300, only the semiconductor package 1000, a mount substrate (the package substrate 1100 or the interposer 1200), and the first semiconductor device 1300 are schematically illustrated.

In FIG. 5A, a system package 2000a may include a semiconductor package 1000, a package substrate 1100, and a first semiconductor device 1300. Comparing with the system package 2000 of FIG. 4B, the system package 2000a may not include an interposer. Accordingly, the semiconductor package 1000 may be mounted just on the package substrate 1100 through a first external connection terminal 300. Also, the first semiconductor device 1300 may be mounted just on the package substrate 1100 through the fourth external connection terminal 1350. A detailed structure or function of each of the package substrate 1100, the semiconductor package 1000, and the first semiconductor device 1300 may be the same as the descriptions of the system package 2000 of FIG. 4B. As illustrated in FIG. 5A, in the system package 2000a, the semiconductor package 1000 and the first semiconductor device 1300 may be connected to each other through a first connection wiring In1 of the package substrate 1100. The first connection wiring In1 may be some of wiring lines of the package substrate 1100.

In FIG. 5B, a system package 2000b may include a semiconductor package 1000, a package substrate 1100a, a first semiconductor device 1300, and a Si-bridge 1400. Comparing with the system package 2000a of FIG. 5A, the system package 2000b according to some implementations may further include the Si-bridge 1400.

The Si-bridge 1400, as illustrated in FIG. 5B, may be disposed in the package substrate 1100a. The Si-bridge 1400 may be disposed in the package substrate 1100a at a corresponding position between the semiconductor package 1000 and the first semiconductor device 1300. Also, the Si-bridge 1400 may overlap a portion of the semiconductor package 1000 and a portion of the first semiconductor device 1300. In the system package 2000b, the semiconductor package 1000 may be disposed at both sides of the first semiconductor device 1300 in an x direction. Accordingly, the Si-bridge 1400 may be disposed at both sides of the first semiconductor device 1300 in the x direction.

The Si-bridge 1400 may include a second connection wiring In2. The Si-bridge 1400 may connect the semiconductor package 1000 to the first semiconductor device 1300 through the second connection wiring In2. As a result, in the system package 2000b, the semiconductor package 1000 and the first semiconductor device 1300 may be connected to each other by using the Si-bridge 1400 which is separately disposed in the package substrate 1100a.

In FIG. 5C, a system package 2000 may be substantially the same as the system package 2000 of FIG. 4B. Accordingly, the system package 2000 may include a semiconductor package 1000, a package substrate 1100, an interposer 1200, and a first semiconductor device 1300. The semiconductor package 1000 may be mounted on the interposer 1200 through a first external connection terminal 300, and the first semiconductor device 1300 may be mounted on the interposer 1200 through a fourth external connection terminal 1350. As illustrated in FIG. 5C, in the system package 2000, the semiconductor package 1000 and the first semiconductor device 1300 may be connected to each other through a third connection wiring In3 of the interposer 1200. The third connection wiring In3 may include wirings of a wiring layer 1210 and a through-via 1220, or may include only the wirings of the wiring layer 1210.

In FIG. 5D, a system package 2000c may include a semiconductor package 1000, a package substrate 1100, an interposer 1200a, a first semiconductor device 1300, and a Si-bridge 1400. Comparing with the system package 2000 of FIG. 5C, the system package 2000c may further include the Si-bridge 1400. Also, the interposer 1200a may be based on an organic material, plastic, and a glass substrate, instead of Si. However, a material of the interposer 1200a is not limited to the materials described above. When the interposer 1200a is based on an organic material, the interposer 1200a may be referred to as a panel interposer.

The Si-bridge 1400, as illustrated in FIG. 5D, may be disposed in the interposer 1200a. The Si-bridge 1400 may be disposed in the interposer 1200a at a corresponding position between the semiconductor package 1000 and the first semiconductor device 1300. Also, the Si-bridge 1400 may overlap a portion of the semiconductor package 1000 and a portion of the first semiconductor device 1300. In the system package 2000c, the semiconductor package 1000 may be disposed at both sides of the first semiconductor device 1300 in an x direction. Accordingly, the Si-bridge 1400 may be disposed at both sides of the first semiconductor device 1300 in the x direction.

The Si-bridge 1400 may include a second connection wiring In2. The Si-bridge 1400 may connect the semiconductor package 1000 to the first semiconductor device 1300 through the second connection wiring In2. As a result, in the system package 2000c, the semiconductor package 1000 and the first semiconductor device 1300 may be connected to each other by using the Si-bridge 1400 which is separately disposed in the interposer 1200a.

FIGS. 6A to 6G are cross-sectional views schematically illustrating an example of a process of a method of manufacturing a semiconductor device according to some implementations. FIGS. 6A to 6G may be described with reference to FIG. 1, and descriptions which are the same as or similar to the descriptions of FIGS. 1 to 5D will be briefly given below or are omitted.

In FIG. 6A, in the method of manufacturing the semiconductor device, a plurality of first initial semiconductor chips 100Ia may be formed on a semiconductor substrate 101W. The semiconductor substrate 101W may be in a wafer state and may be attached and fixed to a first carrier substrate 3000 through an adhesive layer 3200. In FIG. 6A and the following drawings, only a portion corresponding to the semiconductor device 100 of FIG. 1 is illustrated for convenience.

Each of first initial semiconductor chips 100Ia may include a semiconductor substrate 101W, an active layer 110W, a through-via 120a, a lower connection pad 130d, and a lower passivation layer 140Wd. The semiconductor substrate 101W, the active layer 110W, the through-via 120a, the lower connection pad 130d, and the lower passivation layer 140Wd may be the same as the descriptions of the semiconductor substrate 101, the active layer 110, the through-via 120, the lower connection pad 130d, and the lower passivation layer 140d of the semiconductor device 100 of FIG. 1.

To briefly describe a process of forming a plurality of first initial semiconductor chips 100Ia in the semiconductor substrate 101W, an integrated circuit layer may be formed on the semiconductor substrate 101W. The integrated circuit layer may include, for example, integrated devices and wirings connected to the integrated devices. Here, the integrated device may include, for example, a transistor. However, the integrated device is not limited to the transistor.

After the integrated circuit layer is formed, the through-via 120a passing through a portion of the semiconductor substrate 101W may be formed. Because the through-via 120a is formed after the integrated circuit layer is formed, the through-via 120a may correspond to a via-middle structure. The through-via 120a may be the same as the description of the through-via 120 of the semiconductor device 100 of FIG. 1.

After the through-via 120a is formed, a wiring layer may be formed on the integrated circuit layer and the through-via 120a. The wiring layer may include an interlayer insulation layer and wirings. As described above, the integrated circuit layer and the wiring layer may configure the active layer 110W under the semiconductor substrate 101W. Subsequently, the lower passivation layer 140Wd and the lower connection pad 130d may be formed on a lower surface of the active layer 110W. The lower connection pad 130d and the lower passivation layer 140Wd may be the same as the descriptions of the lower connection pad 130d and the lower passivation layer 140d of the semiconductor device 100 of FIG. 1.

After the lower connection pad 130d and the lower passivation layer 140Wd are formed, the semiconductor substrate 101W and an upper structure may be attached and fixed to a carrier substrate 3000 through an adhesive layer 3200. The semiconductor substrate 101W and the upper structure, as illustrated in FIG. 6A, may be attached to the carrier substrate 3000 so that the lower connection pad 130d and the lower passivation layer 140Wd face the carrier substrate 3000.

Subsequently, a portion of a backside surface of the semiconductor substrate 101W may be removed by performing a back-grinding process BG on the semiconductor substrate 101W. The first initial semiconductor chips 100Ia may be formed through the back-grinding process BG.

In FIG. 6B, after the first initial semiconductor chips 100Ia are formed, an upper portion of a backside surface of the semiconductor substrate 101Wa may be removed by performing a Si-recess process S—R. The through-via 120a may protrude from the backside surface of the semiconductor substrate 101Wa through the Si-recess process S—R. The Si-recess process S—R may be performed through a dry-etching process. However, in some implementations, Si-recess process S—R may use a wet-etching process. Second initial semiconductor chips 100Ib may be formed through the Si-recess process S—R.

In FIG. 6C, after the second initial semiconductor chips 1001b are formed, a heat dissipation material layer 150b covering backside surfaces of the first initial semiconductor chips 100Ia and the through-via 120a may be formed. The heat dissipation material layer 150b may include an AlN material layer 152a, a lower insulation material layer 154a, and an upper insulation material layer 156a. In some implementations, the lower insulation material layer 154a may be omitted. The AlN material layer 152a may include AlN. The lower insulation material layer 154a and the upper insulation material layer 156a may include oxide (for example, SiO₂). Third initial semiconductor chips 100Ic may be formed by forming the heat dissipation material layer 150b.

In FIG. 6D, after the third initial semiconductor chips 100Ic are formed, a CMP process CMP may be performed on the heat dissipation material layer 150b and the through-via 120a. An upper surface of the through-via 120 may be exposed through the CMP process CMP. Also, a heat dissipation layer 150 may be formed on an upper surface of the semiconductor substrate 101Wa through the CMP process CMP. The heat dissipation layer 150 may include an AlN layer 152 and a lower insulation layer 154. The heat dissipation layer 150 may be the same as the description of the heat dissipation layer 150 of the semiconductor device 100 of FIG. 1. Because the heat dissipation layer 150 is formed through the CMP process, an upper surface of the through-via 120 and an upper surface of the heat dissipation layer 150 may substantially configure a coplanar surface.

The AlN layer 152 of the heat dissipation layer 150 may function as a stop layer in the CMP process CMP. For reference, the AlN layer 152 may occupy a wide region between through-vias 120 and may occupy a narrow region on the upper surface of the through-via 120. Accordingly, a stop layer function of the AlN layer 152 may be performed by a portion of the AlN layer 152 disposed between through-vias 120. The upper insulation material layer 156a may all be substantially removed in the CMP process CMP. Fourth initial semiconductor chips 100Id may be formed through the CMP process CMP. Furthermore, when the lower insulation material layer 154a is omitted, the heat dissipation layer 150a of the single AlN layer of the semiconductor device 100a of FIG. 2 may be formed through a CMP process.

In FIG. 6E, after the fourth initial semiconductor chips 100Id are formed, an upper passivation material layer 140Wa may be formed on the through-via 120 and the heat dissipation layer 150. The upper passivation material layer 140Wa may include a multilayer. The upper passivation material layer 140Wa may include two or more insulation layers. The upper passivation material layer 140Wa may include, for example, a silicon carbon nitride (SiCN) layer and a SiO₂ layer. However, the number of layers and material of the upper passivation material layer 140Wa are not limited to the numerical value and materials described above. In FIG. 6E, for convenience, the upper passivation material layer 140Wa is illustrated as a single layer. Fifth initial semiconductor chips 100Ie may be formed by forming the upper passivation material layer 140Wa.

In FIG. 6F, after the fifth initial semiconductor chips 100Ie are formed, an upper passivation layer 140Wu may be formed by patterning the upper passivation material layer 140Wa. The upper passivation material layer 140Wa may include open holes H. An upper surface of the through-via 120 may be exposed through the open holes H of the upper passivation layer 140Wu. Patterning of the upper passivation material layer 140Wa may be performed through an exposure process. Sixth initial semiconductor chips 100If may be formed by forming the upper passivation layer 140Wu.

In FIG. 6G, after the sixth initial semiconductor chips 100If are formed, metal (for example, Cu) may be filled in the open holes H of the upper passivation layer 140Wu through a plating process. Subsequently, Cu on the upper passivation layer 140Wu and outside the open holes H may be removed through a CMP process. An upper connection pad 130u may be formed in the open holes H by removing Cu which is on the upper passivation layer 140Wu and outside the open holes H. Seventh initial semiconductor chips 100Ig may be formed by forming the upper connection pad 130u.

Subsequently, the seventh initial semiconductor chips 100Ig may be individualized through a dicing process. The dicing process may be performed through, for example, a plasma dicing process. However, in the method of manufacturing the semiconductor package, the individualization of the seventh initial semiconductor chips 100Ig is not limited to the plasma dicing process. For example, the seventh initial semiconductor chips 100Ig may be individualized through a blade dicing process or a laser dicing process. Also, the dicing process may be referred to as a sawing process.

Subsequently, a connection terminal 160 may be formed on the lower connection pad 130d. The connection terminal 160 may be the same as the description of the connection terminal 160 of the semiconductor device 100 of FIG. 1. The semiconductor device 100 of FIG. 1 may be finished by forming the connection terminal 160. Also, in some implementations, in a case where contamination of the connection terminal 160 may be sufficiently prevented in the dicing process, the connection terminal 160 may be first formed, and then, the singulation of semiconductor chips may be performed through the dicing process.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor device comprising:
a semiconductor substrate having an upper surface and a lower surface;
an active layer on the lower surface of the semiconductor substrate;
a through-via extending through the semiconductor substrate; and
a heat dissipation layer comprising an aluminum nitride (AlN) layer, the heat dissipation layer being on the upper surface of the semiconductor substrate and surrounding a side surface of an upper portion of the through-via.

2. The semiconductor device of claim 1, wherein an upper surface of the heat dissipation layer is coplanar with an upper surface of the through-via.

3. The semiconductor device of claim 1, wherein the heat dissipation layer comprises a lower insulation layer on a lower surface of the AlN layer.

4. The semiconductor device of claim 1, comprising:
a passivation layer on the heat dissipation layer;
an upper connection pad on the through-via in a structure extending through the passivation layer; and
a lower connection pad on a lower surface of the active layer.

5. The semiconductor device of claim 1, wherein the AlN layer comprises compression stress.

6. A semiconductor package comprising:
a base chip;
a plurality of memory chips on the base chip; and
a sealant sealing the plurality of memory chips,
wherein each of the plurality of memory chips comprises:
a first semiconductor substrate,
a first active layer on a lower surface of the first semiconductor substrate,
a first through-via extending through the first semiconductor substrate, and
a first heat dissipation layer comprising an aluminum nitride (AlN) layer, the first heat dissipation layer being on an upper surface of the first semiconductor substrate and surrounding a side surface of an upper portion of the first through-via.

7. The semiconductor package of claim 6, wherein an upper surface of the first heat dissipation layer has a same height level as an upper surface of the first through-via.

8. The semiconductor package of claim 6, wherein each of the plurality of memory chips comprises:
a passivation layer on the first heat dissipation layer;
an upper connection pad on the first through-via in a structure extending through the passivation layer; and
a lower connection pad on a lower surface of the first active layer.

9. The semiconductor package of claim 6, wherein each of the plurality of memory chips is on the base chip or on a memory chip with a connection terminal.

10. The semiconductor package of claim 6, wherein each of the plurality of memory chips is on the base chip or on a memory chip with hybrid copper bonding (HCB).

11. The semiconductor package of claim 6, wherein the base chip comprises:
a second semiconductor substrate,
a second active layer on a lower surface of the second semiconductor substrate,
a second through-via extending through the second semiconductor substrate, and
a second heat dissipation layer comprising an AlN layer, the second heat dissipation layer being on an upper surface of the second semiconductor substrate and surrounding a side surface of an upper portion of the second through-via.

12. The semiconductor package of claim 6, comprising a dummy chip on the plurality of memory chips.

13. The semiconductor package of claim 6,
wherein each of the plurality of memory chips comprises a dynamic random access memory (DRAM) chip, and
wherein the semiconductor package comprises a high bandwidth memory (HBM) package.

14. A semiconductor package comprising:
a package substrate;
a first semiconductor device on the package substrate; and
at least one second semiconductor device on the package substrate and adjacent to the first semiconductor device,
wherein the at least one second semiconductor device comprises a base chip, a plurality of memory chips on the base chip, and a sealant sealing the plurality of memory chips on the base chip, and
wherein each of the plurality of memory chips comprises a semiconductor substrate, an active layer on a lower surface of the semiconductor substrate, a through-via extending through the semiconductor substrate, and a heat dissipation layer comprising an aluminum nitride (AlN) layer, the heat dissipation layer being on an upper surface of the semiconductor substrate and surrounding a side surface of an upper portion of the through-via.

15. The semiconductor package of claim 14, wherein an upper surface of the heat dissipation layer has substantially a same height level as an upper surface of the through-via.

16. The semiconductor package of claim 14, wherein each of the plurality of memory chips comprises:
a passivation layer on the heat dissipation layer;
an upper connection pad on the through-via in a structure extending through the passivation layer; and
a lower connection pad on a lower surface of the active layer.

17. The semiconductor package of claim 14, wherein each of the plurality of memory chips is on the base chip or on a memory chip with a connection terminal or hybrid copper bonding (HCB).

18. The semiconductor package of claim 14,
wherein the first semiconductor device comprises a logic chip, and
wherein the at least one second semiconductor device comprises a high bandwidth memory (HBM) package.

19. The semiconductor package of claim 14, comprising an interface substrate disposed on the package substrate,
wherein the first semiconductor device and the at least one second semiconductor device are on the interface substrate and connected to each other by the interface substrate.

20. The semiconductor package of claim 14, comprising:
(i) an interface substrate on the package substrate and a silicon (Si)-bridge in the interface substrate, or
(ii) a Si-bridge disposed in the package substrate,
wherein the first semiconductor device and the at least one second semiconductor device are connected to each other through the Si-bridge.
